(19) United States
(12) Patent Application Publication
(10) Pub. No.: US 2025/0151487 A1
(43) Pub. Date: May 8, 2025

(54) Display Device

(71) Applicant: LG Display Co., Ltd., Seoul (KR)

(72) Inventors: Jaemin Park, Ansan-si (KR); JongBeom Lee, Paju-si (KR); Soyi Lee, Paju-si (KR)

(21) Appl. No.: 18/906,516

(22) Filed: Oct. 4, 2024

(30) Foreign Application Priority Data
Nov. 6, 2023 (KR) 10-2023-0151786

(51) Int. Cl. H01L 33/60; H01L 25/16; H01L 33/62

(52) U.S. Cl. CPC H10H 20/856; H01L 25/167; H10H 20/857

(57) ABSTRACT

One aspect of the present disclosure provides a display device including: a display panel including a plurality of sub pixels; a reflective electrode disposed in each of the plurality of sub pixels; a first light-emitting element disposed on the reflective electrode; a first connection electrode disposed on the first light-emitting element and configured such that at least a part of the first connection electrode covers the first light-emitting element; and a second light-emitting element disposed on the first connection electrode and configured to overlap the first light-emitting element, in which the first light-emitting element has a larger size than the second light-emitting element. Therefore, the first light-emitting element has a relatively large size, such that the second light-emitting element may be more easily aligned and disposed on the first light-emitting element.

### CROSS-REFERENCE TO RELATED APPLICATION

This application claims the priority of Republic of Korea Patent Application No. 10-2023-0151786 filed on Nov. 6, 2023, which is incorporated by reference in its entirety.

### FIELD

The present disclosure relates to a display device, and more particularly, to a display device using a light-emitting diode (LED).

### DESCRIPTION OF THE RELATED ART

As display devices used for a monitor of a computer, a television (TV) set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### SUMMARY

An object to be achieved by the present disclosure is to provide a display device in which a first light-emitting element and a second light-emitting element are vertically stacked to reduce an area of a sub pixel.

Another object to be achieved by the present disclosure is to provide a display device in which a first light-emitting element has a relatively large size, such that a second light-emitting element may be easily aligned on the first light-emitting element.

Still another object to be achieved by the present disclosure is to provide a display device in which a first connection electrode, which is made of a material with high reflection efficiency, is formed between a first light-emitting element and a second light-emitting element to improve light extraction efficiency.

Yet another object to be achieved by the present disclosure is to provide a display device with improved viewing angle properties and brightness in both forward and lateral directions.

Still yet another object to be achieved by the present disclosure is to provide a display device in which a first connection electrode with high reflection efficiency is formed on a lower portion of a second light-emitting element to improve light extraction efficiency and brightness.

A further object to be achieved by the present disclosure is to provide a display device in which a plurality of opening portions is formed in a first connection electrode to improve efficiency in extracting light emitted from a first light-emitting element.

Another further object to be achieved by the present disclosure is to provide a display device in which a first connection electrode includes a transparent first electrode layer and an opaque second electrode layer, and a second electrode layer is patterned to form a plurality of transmissive portions, thereby improving efficiency in extracting light emitted from a first light-emitting element.

Still another further object to be achieved by the present disclosure is to provide a display device in which a plurality of light-scattering particles is formed around a first light-emitting element to allow light, which is trapped in the display device, to easily exit toward the outside of the display device, thereby improving luminous efficiency and brightness.

Objects of the present disclosure are not limited to the above-mentioned objects, and other objects, which are not mentioned above, can be clearly understood by those skilled in the art from the following descriptions.

One embodiment of the present disclosure provides a display device comprising: a display panel comprising a plurality of sub pixels; a plurality of reflective electrodes, each reflective electrode in a corresponding sub pixel from the plurality of sub pixels; a first light-emitting element on a reflective electrode from the plurality of reflective electrodes; a first connection electrode on the first light-emitting element, the first connection electrode including a part that covers the first light-emitting element; and a second light-emitting element on the first connection electrode and overlaps the first light-emitting element, wherein a size of the first light-emitting element is larger than a size of the second light-emitting element. Therefore, the first light-emitting element has a relatively large size, such that the second light-emitting element may be more easily aligned and disposed on the first light-emitting element.

In one embodiment, a display device comprises: a substrate; a transistor on the substrate; a reflective electrode that is connected to the transistor; a first light-emitting element on the reflective electrode; a second light-emitting element that overlaps the first light-emitting element, the second light-emitting element having a width that is smaller than a width of the first light-emitting element; and a first connection electrode that is between the first light-emitting element and the second light-emitting element, the first connection electrode electrically connected to the first light-emitting element and the second light-emitting element.

Other detailed matters of the exemplary embodiments are included in the detailed description and the drawings.

According to the present disclosure, the first light-emitting element and the second light-emitting element are vertically stacked, which may reduce the area of the sub pixel and implement the display device capable of displaying high-resolution images.

According to the present disclosure, the first light-emitting element has a relatively large size, such that the second light-emitting element may be easily aligned on the first light-emitting element.

According to the present disclosure, the first connection electrode, which is made of a material with high reflection efficiency, is formed between the first light-emitting element and the second light-emitting element, thereby improving viewing angle properties and brightness in both the forward and lateral directions.

According to the present disclosure, the first connection electrode with high reflection efficiency is formed on the lower portion of the second light-emitting element, thereby improving light extraction efficiency and brightness.

According to the present disclosure, a plurality of opening portions are formed in the first connection electrode, thereby improving efficiency in extracting light emitted from the first light-emitting element.

According to the present disclosure, the first connection electrode includes the transparent first electrode layer and the opaque second electrode layer, and the second electrode layer is patterned to form the plurality of transmissive portions, thereby improving efficiency in extracting light emitted from the first light-emitting element.

According to the present disclosure, the plurality of light-scattering particles is formed around the first light-emitting element, thereby allowing light, which is trapped in the display device, to easily exit toward the outside of the display device.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment of the present disclosure;

FIG. 2A is a partial cross-sectional view of the display device according to an embodiment of the present disclosure;

FIG. 2B is a perspective view of a tiling display device according to an embodiment of the present disclosure;

FIG. 3 is a schematic enlarged top plan view of a sub pixel of the display device according to an embodiment of the present disclosure;

FIG. 4 is a cross-sectional view of the sub pixel of the display device according to an embodiment of the present disclosure;

FIG. 5A is a schematic enlarged top plan view of a sub pixel of a display device according to another embodiment of the present disclosure;

FIG. 5B is a schematic enlarged top plan view of the sub pixel of the display device according to another embodiment of the present disclosure;

FIG. 6 is a schematic enlarged top plan view of a sub pixel of a display device according to still another embodiment of the present disclosure;

FIG. 7 is a cross-sectional view of the sub pixel of the display device according to still another embodiment of the present disclosure;

FIGS. 8A, 8B, 8C, 8D, 9A, and 9B are schematic enlarged top plan views of sub pixels of the display device according to various embodiments of the present disclosure; and

FIG. 10 is a cross-sectional view of a sub pixel of a display device according to still yet another embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiments of the present disclosure will be described in detail with reference to accompanying drawings.

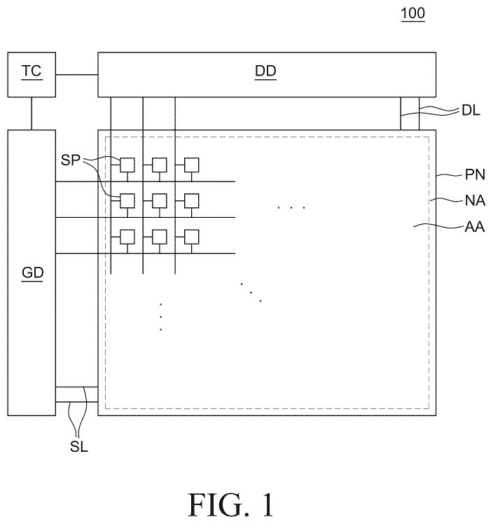

FIG. 1 is a schematic configuration view of a display device according to an embodiment of the present disclosure. For convenience of description, FIG. 1 illustrates only a display panel PN, a gate drive part GD, a data drive part DD, and a timing controller TC among various constituent elements of a display device 100.

With reference to FIG. 1, the display device 100 includes the display panel PN including a plurality of sub pixels SP, the gate drive part GD configured to supply various types of signals to the display panel PN, and the timing controller TC configured to control the data drive part DD, the gate drive part GD, and the data drive part DD.

The gate drive part GD supplies a plurality of scan signals to a plurality of scan lines SL in response to a plurality of gate control signals provided from the timing controller TC. FIG. 1 illustrates that the single gate drive part GD is disposed to be spaced apart from one side of the display panel PN. However, the number and arrangement of the gate drive part GD are not limited thereto.

The data drive part DD supplies data voltages to a plurality of data lines DL in response to a plurality of data control signals and image data provided from the timing controller TC. The data drive part DD may convert image data into data voltages by using a reference gamma voltage and supply the converted data voltages to the plurality of data lines DL.

The timing controller TC aligns image data, which are inputted from the outside, and supplies the image data to the data drive part DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of sub pixels SP. In the display panel PN, the plurality of scan lines SL and the plurality of data lines DL may intersect one another, and the plurality of sub pixels SP may be formed at intersection points between the scan lines SL and the data lines DL.

A display area AA and a non-display area NA may be defined on the display panel PN.

The display area AA is an area of the display device 100 in which images are displayed. The display area AA may include the plurality of sub pixels SP constituting a plurality of pixels PX, and a pixel circuit configured to operate the plurality of sub pixels SP. The plurality of sub pixels SP are minimum units that constitute the display area AA. The n sub pixels SP may constitute a single pixel PX. Thin-film transistors and the like for operating a plurality of light-emitting elements LED may be respectively disposed in the plurality of sub pixels SP. The plurality of light emitting elements LED may be differently defined depending on the type of display panel PN. For example, in case that the display panel PN is an inorganic light-emitting display panel PN, the light-emitting element LED may be a light-emitting diode (LED) or a micro light-emitting diode (micro-LED).

A plurality of signal lines for transmitting various types of signals to the plurality of sub pixels SP are disposed in the display area AA. For example, the plurality of signal lines may include the plurality of data lines DL for supplying data voltages to the plurality of sub pixels SP, and the plurality of scan lines SL for supplying scan signals to the plurality of sub pixels SP. The plurality of scan lines SL may extend in one direction in the display area AA and be connected to the plurality of sub pixels SP. The plurality of data lines DL may extend in a direction different from one direction in the display area AA and be connected to the plurality of sub pixels SP. In addition, the low-potential power line, the high-potential power line, and the like may be further disposed in the display area AA. However, the present disclosure is not limited thereto.

The non-display area NA may be defined as an area in which no image is displayed, i.e., an area extending from the display area AA. The non-display area NA may include link lines and pad electrodes for transmitting signals to the sub pixels SP in the display area AA. Alternatively, the non-display area NA may include drive ICs such as gate drivers IC and data drivers IC.

Meanwhile, the non-display area NA may be positioned on a rear surface of the display panel PN, i.e., a surface on which the sub pixel SP is not present. Alternatively, the non-display area NA may be excluded. However, the present disclosure is not limited to the configuration illustrated in the drawings.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of sub pixels SP by a gate-in-active area (GIA) method in the display area AA.

For example, the data drive part DD and the timing controller TC may be formed on a separate flexible film and a printed circuit board and electrically connect the display panel PN, the data drive part DD, and the timing controller TC by a method of bonding the flexible film and the printed circuit board to a pad electrode formed in the non-display area NA of the display panel PN.

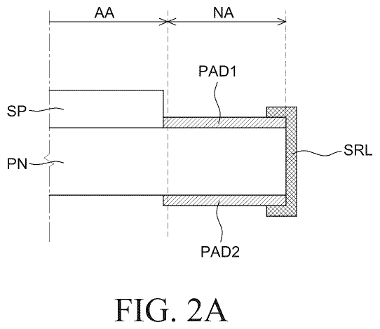

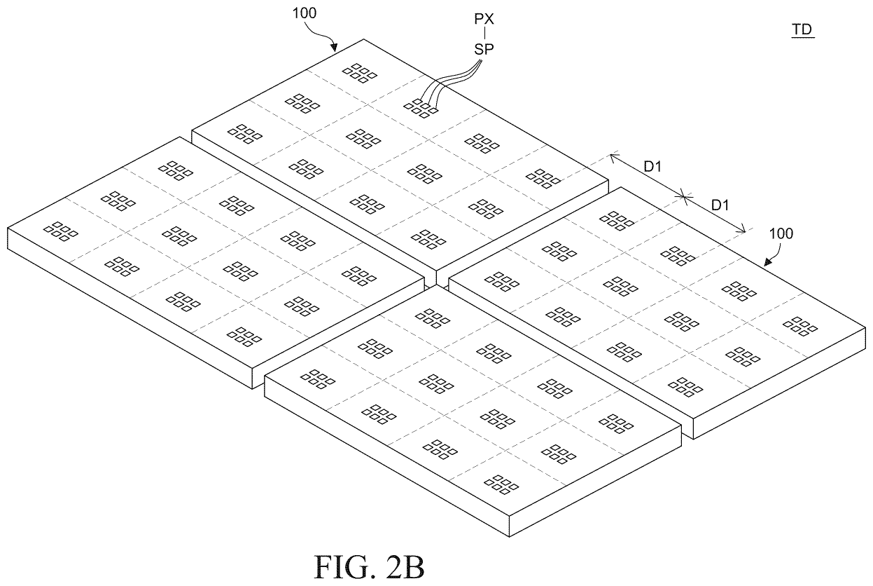

As another example, in case that the gate drive part GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to minimize or at least reduce the non-display area NA on the front surface of the display panel PN. Therefore, in case that the gate drive part GD, the data drive part DD, and the timing controller TC are connected to the display panel PN by the above-mentioned method, a zero bezel in which the bezel is not substantially present may be implemented. A more detailed description will be described with reference to FIGS. 2A and 2B.

FIG. 2A is a partial cross-sectional view of the display device according to the embodiment of the present disclosure. FIG. 2B is a perspective view of a tiling display device according to the embodiment of the present disclosure.

A plurality of pad electrodes for transmitting various types of signals to the plurality of sub pixels SP are disposed in the non-display area NA of the display panel PN. For example, a first pad electrode PAD1 configured to transmit signals to the plurality of sub pixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of sub pixels SP may extend from the display area AA to the non-display area NA and be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of sub pixels SP through the second pad electrode PAD2, the side line SRL, and the first pad electrode PAD1. Therefore, a signal transmission route is defined from the front surface to the side surface and the rear surface of the display panel PN, which may minimize an area of the non-display area NA of the front surface of the display panel PN.

Further, with reference to FIG. 2B, a tiling display device TD having a large screen may be implemented by connecting a plurality of display devices 100. In this case, as illustrated in FIG. 2A, in case that the tiling display device TD is implemented by using the display device 100 with the minimized bezel, a seam area in which no image is displayed between the display devices 100 may be minimized, thereby improving display quality.

For example, the plurality of sub pixels SP may constitute a single pixel PX. An interval DI between an outermost peripheral pixel PX of one display device 100 and an outermost peripheral pixel PX of another display device 100 adjacent to one display device 100 may be implemented to be equal to the interval DI between the pixels PX in one display device 100. Therefore, the seam area may be minimized as a constant interval of the pixels PX is implemented between the display device 100 and the display device 100.

However, as illustrated in FIG. 2A and FIG. 2B, the display device 100 according to the embodiment of the present disclosure may be a general display device in which the bezel is present. However, the present disclosure is not limited thereto.

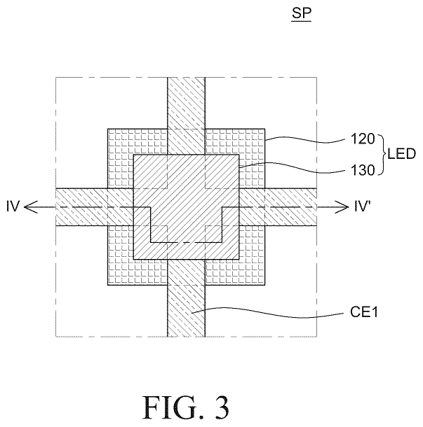

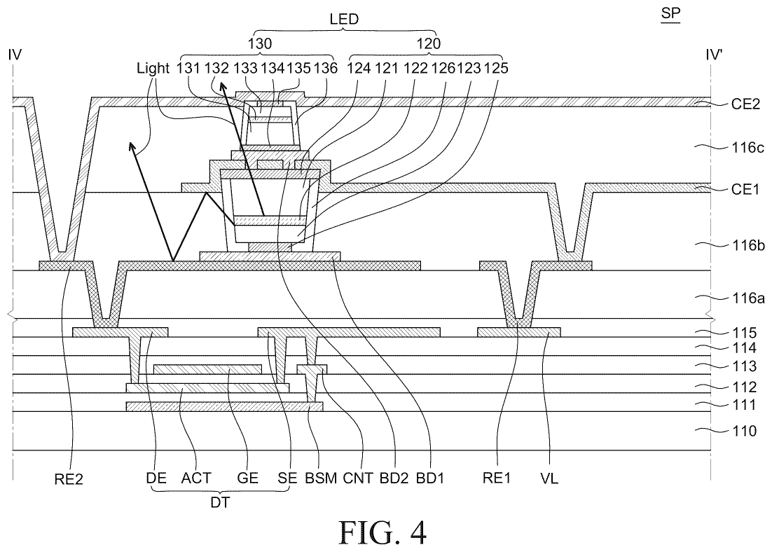

Hereinafter, the sub pixel SP of the display panel PN of the display device 100 according to the embodiment of the present disclosure will be described more specifically with reference to FIGS. 3 and 4.

FIG. 3 is a schematic enlarged top plan view of the sub pixel of the display device according to the embodiment of the present disclosure. FIG. 4 is a cross-sectional view of the sub pixel of the display device according to the embodiment of the present disclosure. For convenience of description, FIG. 3 illustrates a first light emitting element 120, a second light emitting element 130, and a first connection electrode CE1.

With reference to FIGS. 3 and 4, the display panel of the display device 100 according to the embodiment of the present disclosure includes a substrate 110, a buffer layer 111, a gate insulation layer 112, a first interlayer insulation layer 113, a second interlayer insulation layer 114, a first planarization layer 116a, a second planarization layer 116b, and a third planarization layer 116c. Further, the plurality of sub pixels SP each includes a driving transistor DT, a power line VL, an intermediate electrode CNT, a first reflective electrode RE1, a second reflective electrode RE2, the first connection electrode CE1, a second connection electrode CE2, a first bonding layer BD1, a second bonding layer BD2, a first light-emitting element 120, and a second light-emitting element 130. As shown in FIG. 4, the second light-emitting element 140 is farther from the substrate 110 than the first light-emitting element 120.

First, the substrate 110 may be an insulation substrate that supports constituent elements disposed on the display device 100. For example, the substrate 110 may be made of glass, resin, or the like. In addition, the substrate 110 may be made of polymer, plastic, or the like. In several embodiments, the substrate 110 may be made of a plastic material having flexibility. The plurality of pixels PX each including the plurality of sub pixels SP may be formed on the substrate 110 to display images.

A light-blocking layer BSM is disposed on the substrate 110. The light-blocking layer BSM may block light entering an active layer ACT of the driving transistor DT, thereby minimizing a leakage current. For example, the light-blocking layer BSM may be disposed below the active layer ACT of the driving transistor DT and block light entering the active layer ACT. If the light is emitted to the active layer ACT, a leakage current occurs, which may degrade the reliability of the driving transistor DT. Therefore, the light-blocking layer BSM for blocking light may be disposed on the substrate 110, thereby improving the reliability of the driving transistor DT. The light-blocking layer BSM may be made of an opaque electrically conductive material, for example, copper (Cu), aluminum (Al), molybdenum (Mo), nickel (Ni), titanium (Ti), chromium (Cr), or an alloy thereof. However, the present disclosure is not limited thereto.

The buffer layer 111 is disposed on the light-blocking layer BSM and the substrate 110. The buffer layer 111 may be disposed to cover one surface of the substrate 110 and reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. The buffer layer 111 may be excluded in accordance with the type of substrate 110, the type of transistor, or the like. However, the present disclosure is not limited thereto.

Meanwhile, although not illustrated in the drawings, an additional buffer layer may be further disposed between the substrate 110 and the light-blocking layer BSM. Like the buffer layer 111, the additional buffer layer may be disposed to reduce the penetration of moisture or impurities through the substrate 110. For example, the additional buffer layer may be configured as a single layer or multilayer made of silicon oxide (SiOx) or silicon nitride (SiNx). However, the present disclosure is not limited thereto.

Next, the driving transistor DT is disposed on the buffer layer 111. The driving transistor DT includes the active layer ACT, a gate electrode GE, a source electrode SE, and a drain electrode DE. Meanwhile, although not illustrated in the drawings, other transistors, such as a switching transistor, a sensing transistor, and a light emission control transistor, may be additionally disposed in each of the plurality of sub pixels SP, in addition to the driving transistor DT.

First, the active layer ACT of the driving transistor DT is disposed on the buffer layer 111. The active layer ACT may be disposed to overlap the light-blocking layer BSM. The active layer ACT may be made of a semiconductor material such as an oxide semiconductor, amorphous silicon, or polysilicon. However, the present disclosure is not limited thereto. In addition, although not illustrated in the drawings, active layers of other transistors, such as switching transistors, sensing transistors, and light emission control transistors, may each be made of a semiconductor material such as an oxide semiconductor, amorphous silicon, or polysilicon. However, the present disclosure is not limited thereto. In addition, the active layers ACT of the driving transistor DT, the switching transistor, the sensing transistor, and the light emission control transistor may be made of the same material or different materials.

The gate insulation layer 112 is disposed on the active layer ACT. The gate insulation layer 112 is an insulation layer for insulating the active layer ACT and the gate electrode GE. For example, the gate insulation layer 112 may be configured as a single layer or multilayer made of silicon oxide (SiOx) or silicon nitride (SiNx). However, the present disclosure is not limited thereto.

The gate electrode GE is disposed on the gate insulation layer 112. The gate electrode GE may be disposed to overlap the active layer ACT. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulation layer 113 and the second interlayer insulation layer 114 are disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 are insulation layers for protecting components disposed below the first interlayer insulation layer 113 and the second interlayer insulation layer 114. The first interlayer insulation layer 113 and the second interlayer insulation layer 114 may each be configured as a single layer or multilayer made of silicon oxide (SiOx) or silicon nitride (SiNx). However, the present disclosure is not limited thereto.

The source electrode SE and the drain electrode DE are disposed on the second interlayer insulation layer 114. The source electrode SE and the drain electrode DE may be electrically connected to the active layer ACT through the contact holes formed in the first interlayer insulation layer 113 and the second interlayer insulation layer 114. Further, the source electrode SE may be electrically connected to the light-blocking layer BSM through the intermediate electrode CNT. The drain electrode DE may be electrically connected to the first light-emitting element 120 and the second light-emitting element 130 through the first reflective electrode RE1 to be described below. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The intermediate electrode CNT is disposed between the gate insulation layer 112 and the first interlayer insulation layer 113. The intermediate electrode CNT is configured to electrically connect the source electrode SE and the light-blocking layer BSM. The intermediate electrode CNT may be made of the same electrically conductive material as the gate electrode GE. For example, the intermediate electrode CNT may be made of copper (Cu), aluminum (Al), molybdenum (Mo), nickel (Ni), titanium (Ti), chromium (Cr), or an alloy thereof. However, the present disclosure is not limited thereto.

The power line VL is disposed on the second interlayer insulation layer 114. The power line VL may be made of the same electrically conductive material as the source electrode SE and the drain electrode DE. For example, the power line VL may be made of copper (Cu), aluminum (Al), molybdenum (Mo), nickel (Ni), titanium (Ti), chromium (Cr), or an alloy thereof. However, the present disclosure is not limited thereto. The power line VL may be electrically connected to the first light-emitting element 120 and the second light-emitting element 130 through the second reflective electrode RE2 to be described below. The power line VL may be configured as any one of a low-potential power line VL or a high-potential power line VL depending on the configuration of the pixel circuit.

A passivation layer 115 is disposed on the driving transistor DT and the power line VL. The passivation layer 115 is an insulation layer for protecting components disposed below the passivation layer 115. The passivation layer 115 may be configured as a single layer or multilayer made of an inorganic material such as silicon oxide (SiOx) or silicon nitride (SiNx). However, the present disclosure is not limited thereto.

The first planarization layer 116a is disposed on the passivation layer 115. The first planarization layer 116a may planarize an upper portion of the pixel circuit including the driving transistor DT. The first planarization layer 116a may be configured as a single layer or multilayer and made of benzocyclobutene or an acrylic-based organic material, for example. However, the present disclosure is not limited thereto.

A plurality of reflective electrodes are disposed on the first planarization layer 116a. The plurality of reflective electrodes may reflect light, which is emitted from the plurality of light-emitting elements LED, toward an upper side of the substrate 110. At the same time, the plurality of reflective electrodes may serve as electrodes that electrically connect the plurality of light-emitting elements LED, the driving transistor DT, and the power line VL. The plurality of reflective electrodes include the first reflective electrode RE1 and the second reflective electrode RE2 disposed in each of the plurality of sub pixels SP.

The first reflective electrode RE1 is disposed on the first planarization layer 116a. The first reflective electrode RE1 may reflect light, which is emitted from the plurality of light-emitting elements LED, toward the upper side of the substrate 110. At the same time, the first reflective electrode RE1 may serve as an electrode that electrically connects the plurality of light-emitting elements LED and the power line VL. For example, the first reflective electrode RE1 may be electrically connected to the power line VL through contact holes formed in the first planarization layer 116a and the passivation layer 115. The first reflective electrode RE1 may be electrically connected to a first electrode of each of the plurality of light-emitting elements LED through the first connection electrode CE1 to be described below.

The second reflective electrode RE2 is disposed on the first planarization layer 116a. The second reflective electrode RE2 may be disposed to overlap the plurality of light-emitting elements LED and reflect light, which is emitted from the plurality of light-emitting elements LED, toward the upper side of the substrate 110. Further, the second reflective electrode RE2 may be used as an electrode that electrically connects the plurality of light-emitting elements LED and the driving transistor DT. For example, the second reflective electrode RE2 may be electrically connected to the drain electrode DE of the driving transistor DT through the contact holes formed in the first planarization layer 116a and the passivation layer 115. Further, the second reflective electrode RE2 may be electrically connected to a second electrode of each of the plurality of light-emitting elements LED.

Therefore, the plurality of reflective electrodes may include various conductive layers in consideration of light reflection efficiency and resistance. For example, the plurality of reflective electrodes may be made by using an opaque conductive layer, which is made of silver (Ag), aluminum (Al), molybdenum (Mo), titanium (Ti), or an alloy thereof, together with a transparent conductive layer made of indium tin oxide (ITO). However, the structure of the plurality of reflective electrodes is not limited thereto.

The first bonding layer BD1 is disposed on the second reflective electrode RE2. The first bonding layer BD1 may be a conductive joining member configured to electrically connect the first light-emitting element 120 and the second reflective electrode RE2 while fixing (e.g., attaching) the first light-emitting element 120 onto the second reflective electrode RE2. The first bonding layer BD1 may have conductivity to electrically connect the second reflective electrode RE2 and the first light-emitting element 120. Further, the first bonding layer BD1 may have bondability to attach the first light-emitting element 120 to the second reflective electrode RE2. For example, the first bonding layer BD1 may be a bonding layer including conductive particles or an anisotropic conductive film (ACF). However, the present disclosure is not limited thereto. As another example, in case that the first light-emitting element 120 is bonded to the first bonding layer BD1 by thermal compression bonding, the first bonding layer BD1 may be made of eutectic metal. For example, the first bonding layer BD1 may be made of tin (Sn), indium (In), zinc (Zn), lead (Pb), nickel (Ni), gold (Au), platinum (Pt), copper (Cu), or the like. However, the present disclosure is not limited thereto.

The plurality of light-emitting elements LED are disposed on the first planarization layer 116a and the second reflective electrode RE2. The plurality of light-emitting elements LED includes the first light-emitting element 120 and the second light-emitting element 130 disposed in each of the plurality of sub pixels SP. The first light-emitting element 120 and the second light-emitting element 130, which are disposed in the same sub pixel SP, may emit light with the same color. The first light-emitting element 120 and the second light-emitting element 130 may be vertically stacked on top of each other. The second light-emitting element 130 may be disposed on the first light-emitting element 120 such that the first light-emitting element 120 is between the substrate 110 and the second light-emitting element 130. In this case, the first light-emitting element 120, on which the second light-emitting element 130 is disposed, may have a larger size than the second light-emitting element 130. Therefore, the first light-emitting element 120 has a relatively large size, such that the second light-emitting element 130 may be more easily aligned and disposed on the first light-emitting element 120. As shown in FIG. 4, the first light-emitting element 120 has a width that is wider than a width of the second light-emitting element 130. Additionally, a height of the first light-emitting element 120 is greater than a height of the second light-emitting element 130.

The first light-emitting element 120 and the second light-emitting element 130 may be vertical light-emitting elements LED (vertical chips) in which the electrodes are disposed in an upward/downward direction with the light-emitting layers interposed therebetween. For example, the first light-emitting element 120 and the second light-emitting element 130 may each be configured such that an n-type electrode and a p-type electrode may be disposed above or below the light-emitting layer.

In this case, the first light-emitting element 120 and the second light-emitting element 130 may be disposed so that the arrangement directions of the electrodes are opposite to each other. For example, the first light-emitting element 120 may be disposed so that a first n-type electrode is disposed above a first light-emitting layer 122. The second light-emitting element 130 may be disposed so that a second n-type electrode 134 is disposed below a second light-emitting layer 132. Therefore, the first light-emitting element 120 and the second light-emitting element 130 may be disposed to be horizontally symmetric.

The first light-emitting element 120 is disposed on the first bonding layer BD1. The first light-emitting element 120 includes a first n-type semiconductor layer 121, the first light-emitting layer 122, a first p-type semiconductor layer 123, the first n-type electrode 124, a first p-type electrode 125, and a first protective film 126.

The first p-type semiconductor layer 123 is disposed on the first bonding layer BD1, and the first n-type semiconductor layer 121 is disposed on the first p-type semiconductor layer 123. The first n-type semiconductor layer 121 and the first p-type semiconductor layer 123 may each be a layer formed by doping a particular material with n-type and p-type impurities. For example, the first n-type semiconductor layer 121 and the first p-type semiconductor layer 123 may each be a layer formed by doping a material, such as gallium nitride (GaN), indium aluminum phosphide (InAlP), or gallium arsenic (GaAs) with n-type or p-type impurities. The n-type impurities may be silicon (Si), germanium GE, tin (Sn), and the like. The p-type impurities may be magnesium (Mg), zinc (Zn), beryllium (Be), and the like. However, the present disclosure is not limited thereto.

The first light-emitting layer 122 is disposed between the first p-type semiconductor layer 123 and the first n-type semiconductor layer 121. The first light-emitting layer 122 may emit light by receiving positive holes and electrons from the first p-type semiconductor layer 123 and the first n-type semiconductor layer 121. The first light-emitting layer 122 may be configured as a single layer or a multi-quantum well (MQW) structure. For example, the first light-emitting layer 122 may be made of indium gallium nitride (InGaN), gallium nitride (GaN), or the like. However, the present disclosure is not limited thereto.

The first p-type electrode 125 is disposed on a bottom surface of the first p-type semiconductor layer 123. The first p-type electrode 125 may contact the first bonding layer BD1. The first p-type electrode 125 may be electrically connected to the second reflective electrode RE2 through the first bonding layer BD1. Therefore, the first p-type semiconductor layer 123 may be electrically connected to the driving transistor DT through the first p-type electrode 125, the first bonding layer BD1, and the second reflective electrode RE2. The first p-type electrode 125 may be made of an opaque conductive material, such as titanium (Ti), gold (Au), silver (Ag), copper (Cu), or an alloy thereof, with high reflection efficiency and/or a transparent conductive material such as indium tin oxide (ITO) or indium zinc oxide (IZO). However, the present disclosure is not limited thereto.

The first n-type electrode 124 is disposed on a top surface of the first n-type semiconductor layer 121. The first n-type electrode 124 may be disposed to cover the entire top surface of the first n-type semiconductor layer 121. The first n-type electrode 124 is an electrode that electrically connects the first n-type semiconductor layer 121, the first connection electrode CE1, the first reflective electrode RE1, and the power line VL. For example, the first n-type semiconductor layer 121 may be made of a transparent conductive material such as indium tin oxide (ITO) or indium zinc oxide (IZO). However, the present disclosure is not limited thereto.

The first protective film 126 is disposed to surround the first n-type semiconductor layer 121, the first light-emitting layer 122, and the first p-type semiconductor layer 123. The first protective film 126 may be made of an insulating material and protect the first n-type semiconductor layer 121, the first light-emitting layer 122, and the first p-type semiconductor layer 123. The first protective film 126 is disposed to cover a part of a side surface of the first n-type semiconductor layer 121, a part of a side surface of the first light-emitting layer 122, a part of a side surface of the first p-type semiconductor layer 123, and a part of a bottom surface of the first p-type semiconductor layer 123. In this case, a portion of the first p-type electrode 125 may be exposed from the first protective film 126 and contact the first bonding layer BD1. Therefore, the first protective film 126 may be formed to cover at least a part of the first n-type semiconductor layer 121, at least a part of the first light-emitting layer 122, and at least a part of the first p-type semiconductor layer 123, thereby suppressing a short circuit defect and minimizing damage to the first n-type semiconductor layer 121, the first light-emitting layer 122, and the first p-type semiconductor layer 123. The first protective film 126 may be made of any one of a silicon oxide (SiOx)-based material, a silicon nitride (SiNx)-based material, and resin. However, the present disclosure is not limited thereto.

The second planarization layer 116b is disposed on the first light-emitting element 120 and the first planarization layer 116a. The second planarization layer 116b may planarize an upper portion of the substrate 110 on which the first light-emitting element 120 is disposed. The second planarization layer 116b may be disposed to cover at least a part of the first light-emitting element 120 and suppress a defect in which the first connection electrode CE1 is connected to the first p-type semiconductor layer 123 or the like. The second planarization layer 116b may be configured as a single layer or multilayer and made of benzocyclobutene or an acrylic-based organic material, for example. However, the present disclosure is not limited thereto.

The first connection electrode CE1 is disposed on the second planarization layer 116b. The first connection electrode CE1 may be electrically connected to the first reflective electrode RE1 through a contact hole formed in the second planarization layer 116b. The first connection electrode CE1 may be disposed to cover (e.g., overlap) a part of the first light-emitting element 120 and connect to the first n-type electrode 124 of the first light-emitting element 120. Therefore, the first n-type semiconductor layer 121 and the first n-type electrode 124 of the first light-emitting element 120 may be electrically connected to the power line VL through the first connection electrode CE1 and the first reflective electrode RE1. The first connection electrode CE1 may be made of an opaque conductive material, such as titanium (Ti), gold (Au), silver (Ag), copper (Cu), or an alloy thereof, to reflect light, which is emitted from the second light-emitting element 130 disposed on the first connection electrode CE1, toward the upper side of the substrate 110. Therefore, the first connection electrode CE1 may serve as a reflective plate for allowing the light from the second light-emitting element 130 to propagate toward the outside of the display device 100. In one embodiment, the first connection electrode CE1 includes an end that extends past a side surface of the first light-emitting element 120 towards a portion of the second connection electrode CE2 that is disposed in the contact hole without reaching the portion of the second connection electrode CE2. The end of the first connection electrode CE1 also extends past an end of the first bonding layer BD1.

In this case, in order to allow the light, which is emitted from the first light-emitting element 120 disposed below the first connection electrode CE1, to propagate toward the upper side of the substrate 110, the first connection electrode CE1 may be disposed to cover at least a part of the first light-emitting element 120. That is, light propagates through the region between the second connection electrode CE2 and the end of the first connection electrode CE1. For example, a planar shape of the first connection electrode CE1 may be a cross shape, such that the first connection electrode CE1 may overlap a part of the first light-emitting element 120. Therefore, a part of the light from the first light-emitting element 120 may propagate toward the upper side of the substrate 110 through an area in which the first connection electrode CE1 is not disposed.

Meanwhile, another part of the light from the first light-emitting element 120 may be reflected toward a lower side of the substrate 110 by the first connection electrode CE1. However, the light may be reflected again by the second reflective electrode RE2 disposed below the first light-emitting element 120 and propagate away from the upper side of the substrate 110. Therefore, a part of the light emitted from the first light-emitting element 120 may be reflected between the first connection electrode CE1 and the second reflective electrode RE2 and propagate away from the upper side of the substrate 110. Further, the light emitted from the first light-emitting element 120 may be dispersed in a leftward/rightward direction while propagating between the first connection electrode CE1 and the second reflective electrode RE2, which may improve an optical viewing angle and brightness in a lateral direction of the display device 100.

The second bonding layer BD2 is disposed on the first connection electrode CE1. The second bonding layer BD2 may be a conductive joining member that fixes the second light-emitting element 130 onto the first connection electrode CE1 and electrically connects the second light-emitting element 130 and the first connection electrode CE1. The second bonding layer BD2 may be disposed to overlap the first light-emitting element 120. In one embodiment, the second boding layer BD2 is on the first light-emitting element 120. For example, the second bonding layer BD2 is on the first n-type electrode 124. The second bonding layer BD2 may have conductivity to electrically connect the first connection electrode CE1 and the second light-emitting element 130. The second bonding layer BD2 may have bondability to attach the second light-emitting element 130 to the first connection electrode CE1. In addition, the second bonding layer BD2, which overlaps the first light-emitting element 120, may have a high transmittance rate so that the light from the first light-emitting element 120 propagates away from the upper side of the substrate 110 through the second bonding layer BD2 as shown in FIG. 4. For example, the second bonding layer BD2 may be a bonding layer including conductive particles or an anisotropic conductive film (ACF). However, the present disclosure is not limited thereto.

The second light-emitting element 130 is disposed on the second bonding layer BD2. The second light-emitting element 130 includes a second n-type semiconductor layer 131, the second light-emitting layer 132, a second p-type semiconductor layer 133, the second n-type electrode 134, a second p-type electrode 135, and a second protective film 136.

The second n-type semiconductor layer 131 is disposed on the second bonding layer BD2, and the second p-type semiconductor layer 133 is disposed on the second n-type semiconductor layer 131. The second n-type semiconductor layer 131 and the second p-type semiconductor layer 133 may each be a layer formed by doping a particular material with n-type and p-type impurities. For example, the second n-type semiconductor layer 131 and the second p-type semiconductor layer 133 may each be a layer formed by doping a material, such as gallium nitride (GaN), indium aluminum phosphide (InAIP), or gallium arsenic (GaAs) with n-type or p-type impurities. The n-type impurities may be silicon (Si), germanium GE, tin (Sn), and the like. The p-type impurities may be magnesium (Mg), zinc (Zn), beryllium (Be), and the like. However, the present disclosure is not limited thereto.

The second light-emitting layer 132 is disposed between the second p-type semiconductor layer 133 and the second n-type semiconductor layer 131. The second light-emitting layer 132 may emit light by receiving positive holes and electrons from the second p-type semiconductor layer 133 and the second n-type semiconductor layer 131. The second light-emitting layer 132 may be configured as a single layer or a multi-quantum well (MQW) structure. For example, the second light-emitting layer 132 may be made of indium gallium nitride (InGaN), gallium nitride (GaN), or the like. However, the present disclosure is not limited thereto.

The second p-type electrode 135 is disposed on a top surface of the second p-type semiconductor layer 133. The second p-type electrode 135 may adjoin the second connection electrode CE2. The second p-type electrode 135 may be electrically connected to the second reflective electrode RE2 through the second connection electrode CE2. As shown in FIG. 4, a contact hole is formed through the second planarization layer 116b and the third planarization layer 116c and the second connection electrode CE2 contacts the second reflective electrode RE2 through the contact hole. Therefore, the second p-type semiconductor layer 133 may be electrically connected to the driving transistor DT through the second p-type electrode 135, the second connection electrode CE2, and the second reflective electrode RE2. The second p-type electrode 135 may be made of a transparent conductive material such as indium tin oxide (ITO) or indium zinc oxide (IZO). However, the present disclosure is not limited thereto.

The second n-type electrode 134 is disposed on a bottom surface of the second n-type semiconductor layer 131. The second n-type electrode 134 may be disposed to cover the entire bottom surface of the second n-type semiconductor layer 131. The second n-type electrode 134 is an electrode that electrically connects the second n-type semiconductor layer 131, the first connection electrode CE1, the first reflective electrode RE1, and the power line VL. For example, the second n-type semiconductor layer 131 may be made of a transparent conductive material such as indium tin oxide (ITO) or indium zinc oxide (IZO). However, the present disclosure is not limited thereto.

The second protective film 136 is disposed to surround the second n-type semiconductor layer 131, the second light-emitting layer 132, and the second p-type semiconductor layer 133. The second protective film 136 may be made of an insulating material and protect the second n-type semiconductor layer 131, the second light-emitting layer 132, and the second p-type semiconductor layer 133. The second protective film 136 is disposed to cover a part of a side surface of the second n-type semiconductor layer 131, a part of a side surface of the second light-emitting layer 132, a part of a side surface of the second p-type semiconductor layer 133, and a part of a top surface of the second p-type semiconductor layer 133. In this case, the second p-type electrode 135 may be exposed from the second protective film 136 and connect to the second connection electrode CE2. Therefore, the second protective film 136 may be formed to cover at least a part of the second n-type semiconductor layer 131, at least a part of the second light-emitting layer 132, and at least a part of the second p-type semiconductor layer 133, thereby suppressing a short circuit defect and minimizing damage to the second n-type semiconductor layer 131, the second light-emitting layer 132, and the second p-type semiconductor layer 133. The second protective film 136 may be made of any one of a silicon oxide (SiOx)-based material, a silicon nitride (SiNx)-based material, and resin. However, the present disclosure is not limited thereto.

The third planarization layer 116c is disposed on the second light-emitting element 130, the first connection electrode CE1, and the second planarization layer 116b. The third planarization layer 116c may planarize an upper portion of the substrate 110 on which the second light-emitting element 130 is disposed. The third planarization layer 116c may be disposed to cover at least a part of the second light-emitting element 130 and suppress a defect in which the second connection electrode CE2 is connected to the second n-type semiconductor layer 131 or the like. The third planarization layer 116c may be configured as a single layer or multilayer and made of benzocyclobutene or an acrylic-based organic material, for example. However, the present disclosure is not limited thereto.

The second connection electrode CE2 is disposed on the third planarization layer 116c. The second connection electrode CE2 may be electrically connected to the second reflective electrode RE2 through contact holes formed in the third planarization layer 116c and the second planarization layer 116b. The second connection electrode CE2 may be disposed to cover the second light-emitting element 130 and adjoin the second p-type electrode 135 of the second light-emitting element 130. Therefore, the second p-type semiconductor layer 133 and the second p-type electrode 135 of the second light-emitting element 130 may be electrically connected to the driving transistor DT through the second connection electrode CE2 and the second reflective electrode RE2. The second connection electrode CE2 may be made of a transparent conductive material such as indium tin oxide (ITO) or indium zinc oxide (IZO) to allow light, which is emitted from the first light-emitting element 120 and the second light-emitting element 130, to propagate toward the upper side of the substrate 110. However, the present disclosure is not limited thereto.

The light emitted from the second light-emitting element 130 may be reflected toward the upper side of the substrate 110 by the first connection electrode CE1 made of a material with high reflection efficiency. The light, which is emitted from the second light-emitting element 130, may propagate toward the outside of the display device 100 by means of the first connection electrode CE1 that serves as a reflective plate. In this case, no separate reflective plate is disposed above the second light-emitting element 130, but the second connection electrode CE2 made of a transparent electrically conductive material is disposed above the second light-emitting element 130, such that the light may easily propagate toward an upper side of the second light-emitting element 130. Therefore, the light emitted from the second light-emitting element 130 may propagate toward the upper side of the second light-emitting element 130, which may improve brightness in a forward direction of the display device 100.

Meanwhile, both the first n-type electrode 124 of the first light-emitting element 120 and the second n-type electrode 134 of the second light-emitting element 130 may be electrically connected to the power line VL through the first connection electrode CE1 and the first reflective electrode RE1. Further, the first p-type electrode 125 of the first light-emitting element 120 may be electrically connected to the driving transistor DT through the first bonding layer BD1 and the second reflective electrode RE2. The second p-type electrode 135 of the second light-emitting element 130 may also be electrically connected to the driving transistor DT through the second connection electrode CE2 and the second reflective electrode RE2. Therefore, the plurality of light-emitting elements LED may be connected in parallel so that the n-type electrodes may be electrically connected together to the power line VL and the p-type electrodes may be electrically connected together to the driving transistor DT. In a state in which the first light-emitting element 120 and the second light-emitting element 130 are connected in parallel, the first light-emitting element 120 and the second light-emitting element 130 may operate together when the display device 100 operates. Therefore, even though a defect occurs on any one of the first light-emitting element 120 and the second light-emitting element 130 connected in parallel, the remaining light-emitting element LED may emit light, and the sub pixel SP may operate normally.

Further, in the present disclosure, the configuration has been described in which the first n-type semiconductor layer 121 and the first n-type electrode 124 of the first light-emitting element 120 are disposed above the first light-emitting layer 122, and the second p-type semiconductor layer 133 and the second p-type electrode 135 of the second light-emitting element 130 are disposed above the second light-emitting layer 132. However, the arrangement directions of the two light-emitting elements LED may be opposite to each other. However, the present disclosure is not limited thereto. For example, the first light-emitting element 120 may be disposed so that the first p-type semiconductor layer 123 and the first p-type electrode 125 are positioned above the first light-emitting layer 122, and the second light-emitting element 130 may be disposed so that the second n-type semiconductor layer 131 and the second n-type electrode 134 are positioned above the second light-emitting layer 132. In this case, the first p-type semiconductor layer 123, the first p-type electrode 125, the second p-type semiconductor layer 133, and the second p-type electrode 135 may be electrically connected to the first connection electrode CE1 and the power line VL, and the first n-type semiconductor layer 121, the first n-type electrode 124, the second n-type semiconductor layer 131, and the second n-type electrode 134 may be electrically connected to the driving transistor DT.

Therefore, in the display device 100 according to the embodiment of the present disclosure, the first light-emitting element 120 and the second light-emitting element 130, which are vertically stacked and connected in parallel, are disposed in each of the plurality of sub pixels SP, thereby minimizing or at least reducing a defect of the sub pixel SP. The first light-emitting element 120 and the second light-emitting element 130, which define a vertical structure, may be vertically stacked so that the first n-type semiconductor layer 121 and the second n-type semiconductor layer 131 face each other. The first n-type semiconductor layer 121 and the second n-type semiconductor layer 131 may be electrically connected to the power line VL through the first connection electrode CE1. Further, the first p-type semiconductor layer 123 of the first light-emitting element 120 and the second p-type semiconductor layer 133 of the second light-emitting element 130 may also be electrically connected to the driving transistor DT through the first bonding layer BD1 or the second connection electrode CE2. The first light-emitting element 120 and the second light-emitting element 130 may be connected to the pixel circuit in parallel and operate together. Therefore, even though a defect occurs on one of the two light-emitting elements LED, the remaining light-emitting element LED may emit light normally. Therefore, the plurality of light-emitting elements LED may be disposed in each of the plurality of sub pixels SP, which may prepare for a defect of a part of the light-emitting element LED and improve the reliability and display quality of the display device 100.

In the display device 100 according to the embodiment of the present disclosure, the first light-emitting element 120 and the second light-emitting element 130 are vertically stacked, which may reduce the area of the sub pixel SP. If the first light-emitting element 120 and the second light-emitting element 130 are disposed horizontally, it is necessary to ensure both an area in which the first light-emitting element 120 is to be disposed and an area in which the second light-emitting element 130 is to be disposed, which may increase areas required for the plurality of sub pixels SP. Therefore, in the display device 100 according to the embodiment of the present disclosure, the second light-emitting element 130 may be disposed above the first light-emitting element 120, such that the area in which the first light-emitting element 120 is to be disposed and the area in which the second light-emitting element 130 is to be disposed may be integrated into a single area, which may reduce the areas required for the plurality of sub pixels SP. Therefore, more sub pixels SP may be formed in the display device 100, and the display device 100 capable of displaying high-resolution images may be implemented.

In this case, the first light-emitting element 120 may be larger in size than the second light-emitting element 130, such that the second light-emitting element 130 may be more easily aligned and disposed on the first light-emitting element 120. If the first light-emitting element 120 is equal in size to or smaller in size than the second light-emitting element 130, it may be difficult to align the second light-emitting element 130 corresponding to the first light-emitting element 120. Therefore, the first light-emitting element 120 may have a relatively large size compared to the second light-emitting element 130, such that the second light-emitting element 130 may be easily aligned and disposed in the area in which the first light-emitting element 120 is disposed.

In the display device 100 according to the embodiment of the present disclosure, the first connection electrode CE1, which is made of a material with high reflection efficiency, is formed between the first light-emitting element 120 and the second light-emitting element 130 and partially overlaps the first light-emitting element 120 and the second light-emitting element 130, which may improve the optical viewing angle and brightness in the forward and lateral directions of the display device 100. The first light-emitting element 120 disposed below the first connection electrode CE1 may improve the viewing angle and brightness in the lateral direction, and the second light-emitting element 130 disposed on the first connection electrode CE1 may improve the brightness in the forward direction. The light from the first light-emitting element 120 may be dispersed in the leftward/rightward direction while propagating between the first connection electrode CE1 and the second reflective electrode RE2, which may improve the optical viewing angle and brightness in the lateral direction of the display device 100. Further, the light from the second light-emitting element 130 may propagate away from the upper side of the substrate 110 by means of the first connection electrode CE1, which may improve the brightness of the display device 100. Therefore, the first light-emitting element 120, which is configured to allow the most light to propagate in the leftward/rightward direction, and the second light-emitting element 130, which is configured to allow the light to propagate in the forward direction, are disposed together, which may improve the viewing angle properties and brightness of the display device 100.

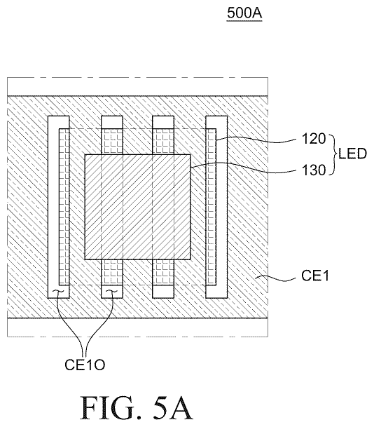

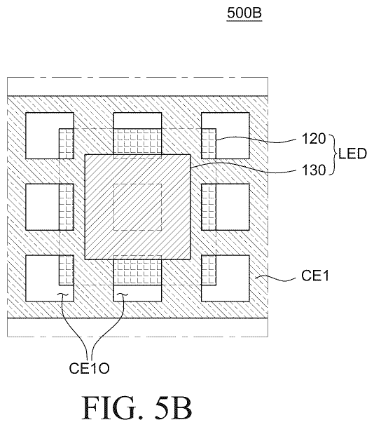

FIG. 5A is a schematic enlarged top plan view of a sub pixel of a display device according to another embodiment of the present disclosure. FIG. 5B is a schematic enlarged top plan view of the sub pixel of the display device according to another embodiment of the present disclosure. Display devices 500A and 500B in FIGS. 5A and 5B are substantially identical in configuration to the display device 100 in FIGS. 1 to 4, except for the first connection electrode CE1. Therefore, repeated descriptions of the identical components will be omitted.

With reference to FIGS. 5A and 5B, the first connection electrode CE1 includes a plurality of opening portions CE1O configured to allow light, which is emitted from the first light-emitting element 120 disposed below the first connection electrode CE1, to propagate toward the outside of the display devices 500A and 500B. The plurality of opening portions CE1O may be disposed to be spaced apart from one another. At least some of the plurality of opening portions CE1O may overlap the first light-emitting element 120. Some of the remaining opening portions CE1O may overlap an area at the periphery of the first light-emitting element 120. A part of the light from the first light-emitting element 120 may propagate toward the upper side of the substrate 110 through the plurality of opening portions CE1O.

The plurality of opening portions CE1O may be formed in various shapes. For example, as illustrated in FIG. 5A, the plurality of opening portions CE1O may be implemented as a plurality of stripe patterns such that the length of each opening portion CE1O is longer than the width of each opening portion CE1O. For example, as illustrated in FIG. 5B, the plurality of opening portions CE1O may be disposed in a plurality of rows and a plurality of columns. Each opening portion CE1O may have a same shape (e.g. square) as shown in FIG. 5B. The first connection electrode CE1 may be formed in a mesh shape by the plurality of opening portions CE1O.

The first light-emitting element 120 and the second light-emitting element 130 may be electrically connected to the first connection electrode CE1 while adjoining a part of the first connection electrode CE1 disposed between the plurality of opening portions CE1O. Therefore, the plurality of opening portions CE1O may be disposed in consideration of the contact areas of the first light-emitting element 120, the second light-emitting element 130, and the first connection electrode CE1. For example, as the areas of the plurality of opening portions CE1O, which overlap the first light-emitting element 120, are increased, the contact areas of the first connection electrode CE1 and the plurality of light-emitting elements LED are decreased, but the light extraction efficiency of the first light-emitting element 120 may be improved. On the contrary, as the areas of the plurality of opening portions CE1O, which overlap the first light-emitting element 120, are decreased, the contact areas of the first connection electrode CE1 and the plurality of light-emitting elements LED are increased, but the light extraction efficiency of the first light-emitting element 120 may deteriorate. Therefore, the sizes and positions of the plurality of opening portions CE1O may be variously designed in collective consideration of the contact areas of the first connection electrode CE1 and the plurality of light-emitting elements LED and the light extraction efficiency of the first light-emitting element 120.

Meanwhile, the first connection electrode CE1 having the plurality of opening portions CE1O may be formed continuously without being divided. In case that the first connection electrode CE1 is divided by the plurality of opening portions CE1O, it may be difficult to normally connect the plurality of light-emitting elements LED and the power line VL. Therefore, the plurality of opening portions CE1O may be formed only in an inner portion of the first connection electrode CE1 or extend from an edge of the first connection electrode CE1 only to a part of an inner side of the first connection electrode CE1.

In the display devices 500A and 500B according to various embodiments of the present disclosure, the plurality of opening portions CE1O is formed in the first connection electrode CE1, such that the light emitted from the first light-emitting element 120 may propagate toward the outside of the display devices 500A and 500B. The plurality of opening portions CE1O may be disposed to overlap the area in which the first light-emitting element 120 is disposed and the area at the periphery of the first light-emitting element 120, and the light emitted from the first light-emitting element 120 may propagate toward the upper side of the substrate 110 through the plurality of opening portions CE1O of the first connection electrode CE1. The plurality of opening portions CE1O may be variously designed in consideration of the contact areas and resistance of the first connection electrode CE1 and the plurality of light-emitting elements LED and the light extraction efficiency of the first light-emitting element 120. Therefore, the plurality of opening portions CE1O may be formed in the first connection electrode CE1, which may improve the efficiency in extracting light emitted from the first light-emitting element 120 and improve the brightness of the display devices 500A and 500B.

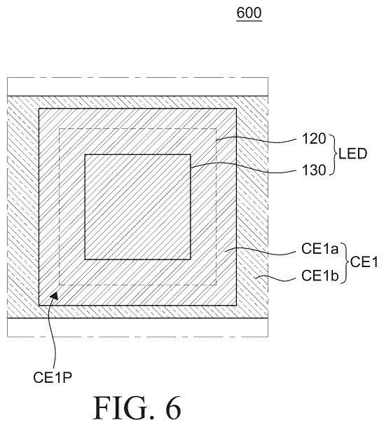

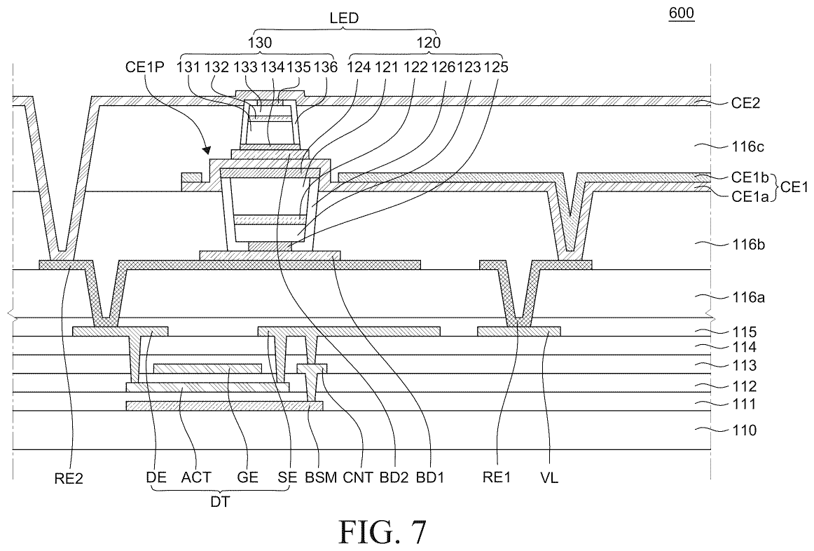

FIG. 6 is a schematic enlarged top plan view of a sub pixel of a display device according to still another embodiment of the present disclosure. FIG. 7 is a cross-sectional view of the sub pixel of the display device according to still another embodiment of the present disclosure. A display device 600 in FIGS. 6 and 7 is substantially identical in configuration to the display device 100 in FIGS. 1 to 4, except that the first connection electrode CE1 includes a plurality of layers. Therefore, repeated descriptions of the identical components will be omitted.

With reference to FIGS. 6 and 7, the first connection electrode CE1 includes a first electrode layer CE1a and a second electrode layer CE1b. The first connection electrode CE1 may have a multilayer structure including the first electrode layer CE1a and the second electrode layer CE1b disposed on the first electrode layer CE1a. The first electrode layer CE1a of the first connection electrode CE1 may be made of a transparent conductive material such as indium tin oxide (ITO) or indium zinc oxide (IZO). The second electrode layer CE1b may be made of an opaque conductive material, such as titanium (Ti), gold (Au), silver (Ag), copper (Cu), or an alloy thereof, with high reflection efficiency.

The first connection electrode CE1 includes a transmissive portion CE1P made by patterning a part of the second electrode layer CE1b. In the transmissive portion CE1P, the second electrode layer CE1b may be patterned to remove the second electrode layer CE1B into the transmissive portion CE1P, and the first electrode layer CE1a may remain. Therefore, the light from the first light-emitting element 120 may pass through the transmissive portion CE1P, in which the first electrode layer CE1a made of a transparent conductive material is disposed, and propagate toward the outside of the display device 600.

The transmissive portion CE1P may be formed by using a half-tone mask. For example, the first connection electrode CE1 may be formed by sequentially forming the first electrode layer CE1a and the second electrode layer CE1b on the front surface of the substrate 110 and etching the first electrode layer CE1a and the second electrode layer CE1b together. In this case, the transmissive portion CE1P, in which only the first electrode layer CE1a is formed, may be formed by using the half-tone mask and additionally etching the second electrode layer CE1b disposed in the transmissive portion CE1P. Therefore, the half-tone mask may be used to etch only the second electrode layer CE1b on the first electrode layer CE1a in the transmissive portion CE1P without etching the first electrode layer CE1a so that the first electrode layer CE1a remains without change.

The transmissive portion CE1P may be variously designed in consideration of the light extraction efficiency or light extraction directions of the first light-emitting element 120. For example, as illustrated in FIG. 6, the transmissive portion CE1P, which has a larger size than the first light-emitting element 120 in a plan view, may be formed to allow the light from the first light-emitting element 120 to propagate toward the upper side of the substrate 110.

In this case, the first connection electrode CE1 has a structure in which the first electrode layer CE1a is formed entirely, and the second electrode layer CE1b is partially formed in the first electrode layer CE1a. Therefore, even though the second electrode layer CE1b is patterned in various shapes, the power line VL and the light-emitting element LED may be easily and electrically connected through the first electrode layer CE1a. That is, because the first electrode layer CE1a serves to electrically connect the light-emitting element LED and the power line VL, the transmissive portion CE1P and the second electrode layer CE1b may be formed in various shapes. For example, even though a part of the second electrode layer CE1b is formed in an island shape by the transmissive portion CE1P, the first electrode layer CE1a may electrically connect the second electrode layers CE1b, and the second electrode layer CE1b may serve as an electrode.

Further, the second electrode layer CE1b may be disposed on a part of the remaining first connection electrode CE1, which excludes the transmissive portion CE1P, and serve as a reflective plate that reflects the light from the second light-emitting element 130 toward the upper side of the substrate 110. Therefore, the second electrode layer CE1b of the first connection electrode CE1 is made of an opaque conductive material excellent in reflection efficiency, which may improve the light extraction efficiency of the second light-emitting element 130. The transmissive portion CE1P is formed in the second electrode layer CE1b, which may improve the light extraction efficiency of the first light-emitting element 120.

Therefore, in the display device 600 according to still another embodiment of the present disclosure, the first connection electrode CE1 includes the first electrode layer CE1a made of a transparent conductive material, and the second electrode layer CE1b made of an opaque conductive material with high reflection efficiency, and only the second electrode layer CE1b is partially patterned, thereby improving both the light extraction efficiency of the first light-emitting element 120 and the light extraction efficiency of the second light-emitting element 130. For example, a part of the second electrode layer CE1b, which is adjacent to the first light-emitting element 120, may be patterned, such that the transmissive portion CE1P, in which only the first electrode layer CE1a is disposed, may be formed in the first connection electrode CE1. The light from the first light-emitting element 120 may propagate toward the upper side of the substrate 110 through the transmissive portion CE1P. Further, the remaining second electrode layer CE1b, which remains without being patterned, may serve as a reflective plate that reflects light, which is emitted from the second light-emitting element 130, toward the upper side of the substrate 110. Therefore, the first connection electrode CE1 includes the transparent first electrode layer CE1a and the opaque second electrode layer CE1b partially patterned, which may improve the light extraction efficiency of the plurality of light-emitting elements LED and improve the brightness of the display device 600.

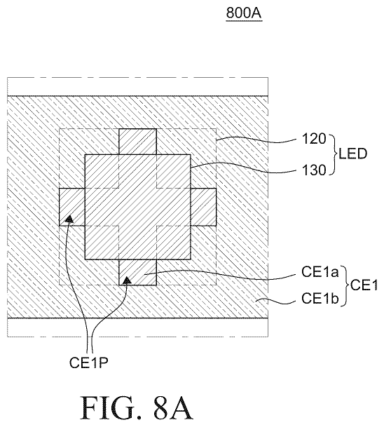

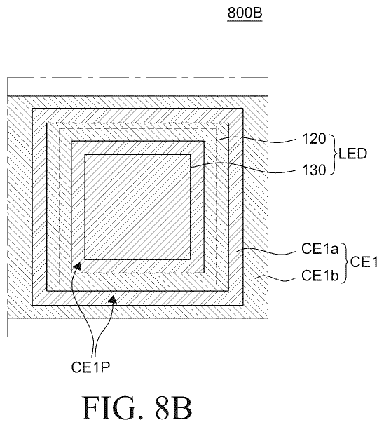

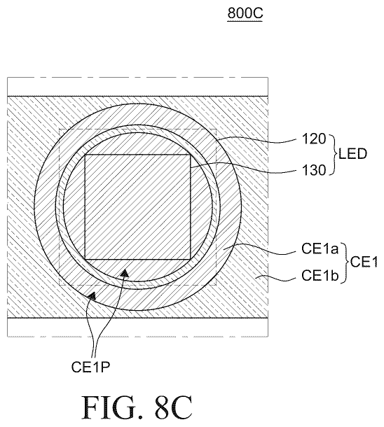

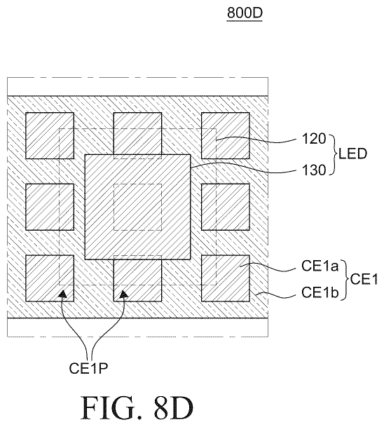

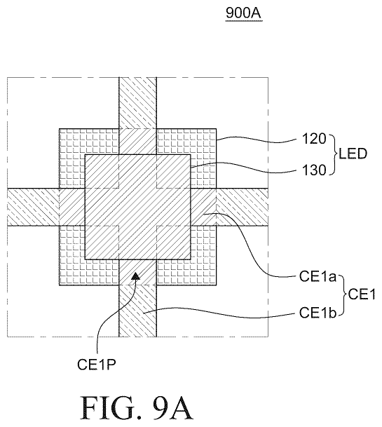

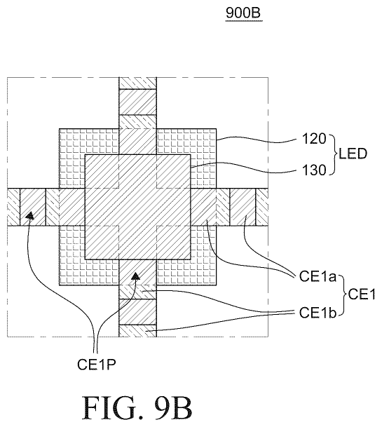

FIGS. 8A to 9B are schematic enlarged top plan views of sub pixels of display devices 800A, 800B, 800C, 800D, 900A, and 900B according to various embodiments of the present disclosure. The display devices 800A, 800B, 800C, 800D, 900A, and 900B in FIGS. 8A to 9B are substantially identical in configuration to the display device 600 in FIGS. 6 and 7, except for the shapes of the first connection electrode CE1. Therefore, repeated descriptions of the identical components will be omitted.

With reference to FIGS. 8A to 8D, the first connection electrode CE1 may be disposed to cover the entire first light-emitting element 120. Further, the transmissive portions CE1P having various shapes may be formed in the first connection electrode CE1, which may improve the light extraction efficiency of the first light-emitting element 120.

For example, with reference to FIG. 8A, the transmissive portion CE1P may be formed by patterning a part of the second electrode layer CE1b that overlaps the first light-emitting element 120 to remove the part of the second electrode layer CE1b. For example, the transmissive portion CE1P having a cross shape may be formed by patterning, in a cross shape, a part of the second electrode layer CE1b that overlaps the first light-emitting element 120. In this case, the light from the first light-emitting element 120 may propagate in the upward/downward direction and the leftward/rightward direction.

In addition, although not illustrated in the drawings, the plurality of transmissive portions CE1P may be formed in a direction in which the light is intended to be extracted, such that the optical viewing angle properties and brightness may be controlled in the corresponding direction. For example, the transmissive portions CE1P are formed in the left and right areas of the first light-emitting element 120, which may improve the optical viewing angle properties in the leftward/rightward direction.

With reference to FIGS. 8B and 8C, the plurality of transmissive portions CE1P may be formed by patterning a part of the second electrode layer CE1b in a closed loop shape to remove the part of the second electrode layer CE1b. One of the plurality of transmissive portions CE1P may overlap the first light-emitting element 120 and be the transmissive portion CE1P with a closed loop shape. The remaining part of the plurality of transmissive portions CE1P may be the transmissive portion CE1P having a closed loop shape and disposed adjacent to the first light-emitting element 120. In this case, when a planar shape of the first light-emitting element 120 is a quadrangular shape, the plurality of transmissive portions CE1P may have a quadrangular closed loop shape corresponding to the planar shape of the first light-emitting element 120. As another example, the planar shape of the first light-emitting element 120 may be a quadrangular shape, whereas the plurality of transmissive portions CE1P may have a circular closed loop shape. Therefore, the transmissive portions CE1P having a closed loop shape are formed in the area, which overlaps the first light-emitting element 120, and the area adjacent to the first light-emitting element 120, which may allow the light from the first light-emitting element 120 to uniformly propagate in all directions.

With reference to FIG. 8D, the second electrode layer CE1b may be formed in a mesh shape by forming the plurality of transmissive portions CE1P in the second electrode layer CE1b. Some of the plurality of transmissive portions CE1P may at least partially overlap the first light-emitting element 120. Some of the remaining transmissive portions CE1P may be disposed in an area adjacent to the first light-emitting element 120. The plurality of transmissive portions CE1P may be disposed in a plurality of rows and a plurality of columns. The first connection electrode CE1 including the plurality of transmissive portions CE1P may be formed in a mesh shape. The light extraction efficiency of the first light-emitting element 120 may be adjusted by adjusting the sizes of the plurality of transmissive portions CE1P. In this case, all the plurality of transmissive portions CE1P is described as having the same size. However, the plurality of transmissive portions CE1P may have different sizes. However, the present disclosure is not limited thereto.

With reference to FIGS. 9A and 9B, the first connection electrode CE1 may be disposed to cover a part of the first light-emitting element 120. Therefore, the light from the first light-emitting element 120 may propagate away from the upper side of the substrate 110 through the area, in which the first connection electrode CE1 is not disposed, and through the transmissive portion CE1P of the first connection electrode CE1. The first connection electrode CE1 is disposed to cover a part of the first light-emitting element 120, which may improve the light extraction efficiency of the first light-emitting element 120.

For example, with reference to FIG. 9A, a planar shape of the first connection electrode CE1 is a cross shape, such that the first connection electrode CE1 may be disposed to cover a part of the first light-emitting element 120. Therefore, the first light-emitting element 120 may include a portion, which overlaps the first connection electrode CE1, and a portion that does not overlap (e.g., non-overlapping) the first connection electrode CE1. Further, the second electrode layer CE1b is patterned in the area that overlaps the first light-emitting element 120, such that the first electrode layer CE1a of the first connection electrode CE1 may be disposed on the first light-emitting element 120. Therefore, the light, which is emitted from the first light-emitting element 120, may propagate toward the upper side of the substrate 110 through the transmissive portion CE1P of the first connection electrode CE1 and the portion of the first light-emitting element 120 that does not overlap the first connection electrode CE1.

For example, with reference to FIG. 9B, a part of the second electrode layer CE1b, which does not overlap the first light-emitting element 120, may also be patterned, thereby increasing the areas of the plurality of transmissive portions CE1P. The plurality of transmissive portions CE1P may be additionally formed by partially patterning the second electrode layer CE1b disposed in the portion of the first connection electrode CE1 that does not overlap the first light-emitting element 120. Therefore, the plurality of transmissive portions CE1P is formed in both the area, which overlaps the first light-emitting element 120, and the area, which does not overlap the first light-emitting element 120, which may improve the luminous efficiency of the first light-emitting element 120.

Therefore, in the display devices 800A, 800B, 800C, 800D, 900A, and 900B according to various embodiments of the present disclosure, the shape of the first connection electrode CE1 and the shapes of the plurality of transmissive portions CE1P formed in the first connection electrode CE1 are variously implemented, which may improve the luminous efficiency of the plurality of light-emitting elements LED. For example, the transmissive portion CE1P, which is formed by patterning the second electrode layer CE1b, may be formed in consideration of the size or shape of the first light-emitting element 120, the optical viewing angle, and the like. For example, the plurality of transmissive portions CE1P is formed in a closed loop shape corresponding to the planar shape of the first light-emitting element 120, which may allow the light, which is emitted from the first light-emitting element 120, to propagate uniformly in all directions. Further, the first connection electrode CE1 is disposed to cover only a part of the first light-emitting element 120, such that the light emitted from the first light-emitting element 120 may be more easily extracted to the outside of the display devices 800A, 800B, 800C, 800D, 900A, and 900B.

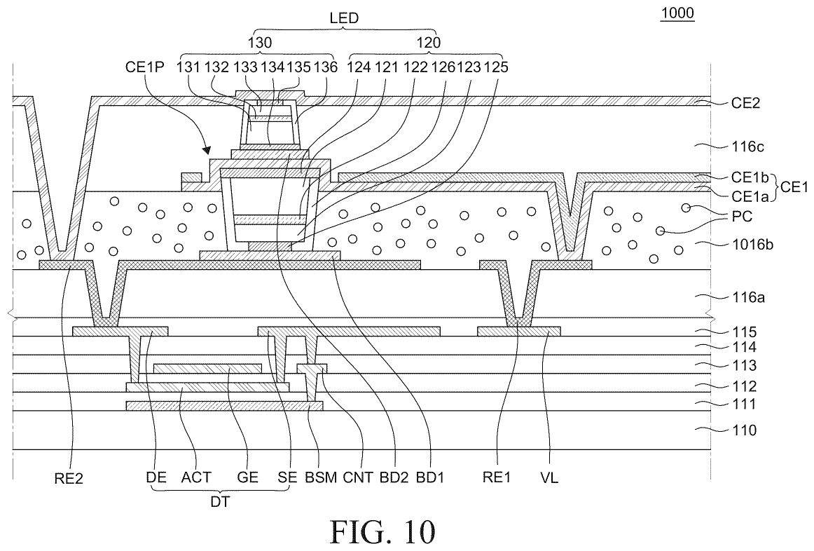

FIG. 10 is a cross-sectional view of a sub pixel of a display device according to still yet another embodiment of the present disclosure. A display device 1000 in FIG. 10 is substantially identical in configuration to the display device 600 in FIGS. 6 and 7, except for a second planarization layer 1016b. Therefore, repeated descriptions of the identical components will be omitted.

With reference to FIG. 10, the second planarization layer 1016b may be disposed to surround the first light-emitting element 120. The second planarization layer 1016b may include a plurality of light-scattering particles PC, which may improve the efficiency in extracting light emitted from the first light-emitting element 120. For example, a part of the light emitted from the first light-emitting element 120 may not propagate toward the outside of the substrate 110 because of the second electrode layer CE1b. The light may be scattered by the plurality of light-scattering particles PC and propagate in various directions. Therefore, the light may be scattered in various directions by the plurality of light-scattering particles PC, which may increase the probability that the light is extracted from the first light-emitting element 120 to the transmissive portion CE1P, in which the second electrode layer CE1b is not disposed, and the area disposed outside the first connection electrode CE1. For example, the light-scattering particles PC may be nano-particles, such as titanium oxide (TiO₂), zirconium oxide (ZrO₂), and barium titanate (BaTiO₃), with fine sizes. However, the present disclosure is not limited thereto.

Meanwhile, the second planarization layer 1016b including the plurality of light-scattering particles PC may also be applied to the display device 100 in FIGS. 1 to 4, the display devices 500A and 500B in FIGS. 5A and 5B, and the display devices 800A, 800B, 800C, 800D, 900A, and 900B in FIGS. 8A to 9B, in addition to the display device 600 in FIGS. 6 and 7.

Therefore, in the display device 1000 according to still yet another embodiment of the present disclosure, the plurality of light-scattering particles PC is provided in the second planarization layer 1016b that surrounds the first light-emitting element 120, such that the light from the first light-emitting element 120 may be scattered and easily propagate toward the outside of the substrate 110. A part of the light from the first light-emitting element 120 cannot exit toward the outside of the substrate 110 because of the second electrode layer CE1b made of an opaque conductive material. However, this part of the light may be scattered by the light-scattering particles PC and propagate in the other directions. Therefore, the routes for the light, which does not exit toward the outside of the display device 1000, may be changed by the plurality of light-scattering particles PC, which may increase the amount of light propagating toward the outside of the display device 1000. Therefore, it is possible to improve the efficiency of the display device 1000 and reduce the power consumption.

The exemplary embodiments of the present disclosure can also be described as follows:

According to an aspect of the present disclosure, a display device includes a display panel comprising a plurality of sub pixels, a reflective electrode disposed in each of the plurality of sub pixels, a first light-emitting element disposed on the reflective electrode, a first connection electrode disposed on the first light-emitting element and configured such that at least a part of the first connection electrode covers the first light-emitting element, and a second light-emitting element disposed on the first connection electrode and configured to overlap the first light-emitting element, the first light-emitting element has a larger size than the second light-emitting element.

The first light-emitting element may include a first light-emitting layer, a first n-type electrode disposed on the first light-emitting layer, and a first p-type electrode disposed below the first light-emitting layer. The second light-emitting element may include a second light-emitting layer, a second n-type electrode disposed below the second light-emitting layer, and a second p-type electrode disposed on the second light-emitting layer, and the first n-type electrode and the second n-type electrode may be electrically connected to the first connection electrode.

The display device may further include a second connection electrode disposed on the second light-emitting element, the first p-type electrode may be electrically connected to the reflective electrode, and the second connection electrode may be electrically connected to the second p-type electrode, the reflective electrode, and the first p-type electrode.

The first light-emitting element and the second light-emitting element may be connected in parallel.

The first connection electrode may be made of an opaque conductive material and configured to reflect light emitted from the first light-emitting element and light emitted from the second light-emitting element.

The first connection electrode may be disposed to overlap a part of the first light-emitting element, and the first light-emitting element may include a portion, which overlaps the first connection electrode, and a portion that does not overlap the first connection electrode.

The first connection electrode may include a plurality of opening portions that at least partially overlaps the first light-emitting element.

The first connection electrode may include a first electrode layer made of a transparent conductive material, and a second electrode layer disposed on the first electrode layer, made of an opaque conductive material, and configured to reflect light emitted from the first light-emitting element and light emitted from the second light-emitting element.

The first connection electrode may include one or more transmissive portions formed by patterning the second electrode layer so that only the first electrode layer may be disposed in the transmissive portion, and a part of the light emitted from the first light-emitting element may pass through the transmissive portion and propagate toward an upper side of the first light-emitting element.

The one or more transmissive portions may be disposed to at least partially overlap the first light-emitting element.

The one or more transmissive portions may have a closed loop shape.

The display device may further include a planarization layer disposed between the reflective electrode and the first connection electrode and disposed to surround the first light-emitting element, and a plurality of light-scattering particles disposed in the planarization layer, a part of the light emitted from the first light-emitting element may be scattered by the plurality of light-scattering particles.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device comprising:
a display panel comprising a plurality of sub pixels;
a plurality of reflective electrodes, each reflective electrode in a corresponding sub pixel from the plurality of sub pixels;
a first light-emitting element on a reflective electrode from the plurality of reflective electrodes;
a first connection electrode on the first light-emitting element, the first connection electrode including a part that covers the first light-emitting element; and
a second light-emitting element on the first connection electrode and overlaps the first light-emitting element,
wherein a size of the first light-emitting element is larger than a size of the second light-emitting element.

2. The display device of claim 1, wherein the first light-emitting element comprises:
a first light-emitting layer;
a first n-type electrode above the first light-emitting layer; and
a first p-type electrode below the first light-emitting layer,
wherein the second light-emitting element comprises:
a second light-emitting layer;
a second n-type electrode below the second light-emitting layer and above the first n-type electrode; and
a second p-type electrode above the second light-emitting layer,
wherein the first n-type electrode and the second n-type electrode are electrically connected to the first connection electrode.

3. The display device of claim 2, further comprising:
a second connection electrode on the second light-emitting element, the second connection electrode electrically connected to the second p-type electrode, the reflective electrode, and the first p-type electrode,
wherein the first p-type electrode is electrically connected to the reflective electrode.

4. The display device of claim 3, wherein the first light-emitting element and the second light-emitting element are connected in parallel.

5. The display device of claim 2, wherein the first connection electrode comprises an opaque conductive material and reflects light emitted from the first light-emitting element and light emitted from the second light-emitting element.

6. The display device of claim 5, wherein the part of the first connection electrode overlaps a first portion of the first light-emitting element, and the first light-emitting element includes a second portion that is non-overlapping with the first connection electrode.

7. The display device of claim 5, wherein the first connection electrode comprises a plurality of opening portions that at least partially overlaps the first light-emitting element.

8. The display device of claim 2, wherein the first connection electrode comprises:
a first electrode layer including a transparent conductive material; and
a second electrode layer on the first electrode layer, the second electrode layer including an opaque conductive material,
wherein the second electrode layer reflects light emitted from the first light-emitting element and light emitted from the second light-emitting element.

9. The display device of claim 8, wherein the first connection electrode comprises one or more transmissive portions that lack the second electrode layer and the first electrode layer is in the one or more transmissive portions, and
wherein a part of the light emitted from the first light-emitting element passes through the one or more transmissive portions and propagates toward an upper side of the first light-emitting element.

10. The display device of claim 9, wherein the one or more transmissive portions at least partially overlap the first light-emitting element.

11. The display device of claim 9, wherein the one or more transmissive portions have a closed loop shape.

12. The display device of claim 2, further comprising:
a planarization layer between the reflective electrode and the first connection electrode, the planarization layer surrounding the first light-emitting element; and
a plurality of light-scattering particles disposed in the planarization layer,
wherein a part of light emitted from the first light-emitting element is scattered by the plurality of light-scattering particles.

13. The display device of claim 1, wherein the first light-emitting element comprises:
a first light-emitting layer,
a first n-type semiconductor layer,
a first p-type semiconductor layer and
a first protective film, the first protective film covering at least a part of the first n-type semiconductor layer, at least a part of the first light-emitting layer, and at least a part of the first p-type semiconductor layer, and
wherein the second light-emitting element comprises:
a second light-emitting layer,
a second n-type semiconductor layer,
a second p-type semiconductor layer and
a second protective film, the second protective film covering at least a part of the second n-type semiconductor layer, at least a part of the second light-emitting layer, and at least a part of the second p-type semiconductor layer.

14. A display device comprising:
a substrate;
a transistor on the substrate;
a reflective electrode that is connected to the transistor;
a first light-emitting element on the reflective electrode;
a second light-emitting element that overlaps the first light-emitting element, the second light-emitting element having a width that is smaller than a width of the first light-emitting element; and
a first connection electrode that is between the first light-emitting element and the second light-emitting element, the first connection electrode electrically connected to the first light-emitting element and the second light-emitting element.

15. The display device of claim 14, wherein the second light-emitting element is farther from the substrate than the first light-emitting element.

16. The display device of claim 14, further comprising:
a second connection electrode that overlaps the first light-emitting element and the second light-emitting element, the second connection electrode connected to the reflective electrode.

17. The display device of claim 16, wherein the first light-emitting element comprises:
a first light-emitting layer;
a first n-type electrode at a first side of the first light-emitting layer; and
a first p-type electrode at a second side of the first light-emitting layer that is closer to the substrate than the first side of the first light-emitting layer, the first p-type electrode electrically connected to the reflective electrode,
wherein the second light-emitting element comprises:
a second light-emitting layer;
a second p-type electrode that is at a first side of the second light-emitting layer, the second p-type electrode connected to the second connection electrode and electrically connected to the reflective electrode and the first p-type electrode; and
a second n-type electrode at a second side of the second light-emitting layer that is closer to the substrate than the first side of the second light-emitting layer, the second n-type electrode electrically connected to the first connection electrode and the first n-type electrode.

18. The display device of claim 16, further comprising:
a planarization layer between the reflective electrode and the first connection electrode; and
a contact hole through the planarization layer, wherein the second connection electrode is connected to the reflective electrode through the contact hole.

19. The display device of claim 18, further comprising:
a plurality of light-scattering particles disposed in the planarization layer.

20. The display device of claim 18, wherein the first connection electrode includes an end that extends past a side surface of the first light-emitting element towards a portion of the second connection electrode that is disposed in the contact hole without reaching the portion of the second connection electrode.

21. The display device of claim 20, further comprising:
a bonding layer between the reflective electrode and the first light-emitting element, the bonding layer attaching the first light-emitting element to the reflective electrode,
wherein the end of the first connection electrode extends past an end of the bonding layer.

22. The display device of claim 14, wherein the first connection electrode comprises:
a first electrode layer including a transparent conductive material; and
a second electrode layer on the first electrode layer, the second electrode layer including an opaque conductive material.

23. The display device of claim 22, wherein the first connection electrode comprises one or more transmissive portions that lack the second electrode layer and the first electrode layer is in the one or more transmissive portions.

24. The display device of claim 23, wherein the one or more transmissive portions at least partially overlap the first light-emitting element.

25. The display device of claim 14, wherein the first light-emitting element and the second light-emitting element emit a same color of light and are connected in parallel.
